(19) United States
(12) Patent Application Publication
(10) Pub. No.: US 2005/0212179 A1
(43) Pub. Date: Sep. 29, 2005

(54) Method and apparatus for reforming laminated films and laminated films manufactured thereby

(75) Inventors: Minoru Honda, Amagasaki-shi (JP); Hiroyuki Nagai, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/058,319

(22) Filed: Feb. 16, 2005

(30) Foreign Application Priority Data
Feb. 16, 2004 (JP) 2004-039041

(51) Int. Cl. H01J 37/30; H05B 6/00; B29C 55/00

(52) U.S. Cl. 264/480; 264/485

(57) ABSTRACT

There is provided a method for reforming laminated films, which simultaneously reforms a plurality of laminated films by irradiating electron beams on the laminated films. The method for reforming laminated films includes the steps of forming a lower film by coating a first low dielectric material in liquid form on a surface of a substrate; forming an upper film by coating a second low dielectric material in liquid form on the lower film; and irradiating electron beams on the lower and upper film. A laminated film manufacturing system includes a mounting table for mounting thereon a substrate on which the laminated films are formed; and an electron beam unit having a plurality of electron beam tubes for irradiating electron beams on the laminated films to thereby simultaneously reform the films.

### FIELD OF THE INVENTION

The present invention relates to a method for reforming laminated films and laminated films manufactured thereby; and, more particularly, to a method for reforming laminated films capable of increasing a throughput of a reforming process performed on laminated films while increasing a mechanical strength and an adhesive strength between films and laminated films manufactured thereby.

### BACKGROUND OF THE INVENTION

A wiring structure tends to become more complicated and a reduction of a parasitic capacitance caused by insulating films between wirings gets more important as the relentless drive toward high integration and high speed of semiconductor devices gets ever stronger. Accordingly, recently, in order to reduce the parasitic capacitance caused by the insulating films between the wirings in the complicated wiring structure, various organic and inorganic materials of a low dielectric constant have been developed, wherein such organic materials are used as a low-k material for an interlayer insulating film, a protective film or the like. The low-k material is known as a spin-on dielectric (SOD) film formed by the low-k film material coated on a surface of an object to be processed and a heat treatment performed thereon with the use of, e.g., a spin coater and a bake furnace. However, the SOD film is formed by coating a liquid material and some SOD films are formed to have a high porosity for a low dielectric constant and, therefore, the SOD film has a low mechanical strength.

Therefore, the mechanical strength thereof is made to be strengthened by coating the SOD film with a CVD film or the like. For example, as shown in FIG. 6B, a Low-k material is coated on a base layer 1 illustrated in FIG. 6A by employing a spin coating method and, then, a specific heat treatment is performed thereon, thereby forming a SOD film 2. Further, as depicted in FIG. 6C, a CVD film 3 serving as a hard mask is formed on the SOD film 2 by employing a CVD method to form laminated films, thereby obtaining a desired mechanical strength. However, in case of laminated films depicted in FIG. 6C, due to a difference in materials between the SOD film 2 and the CVD film 3, the adhesivity therebetween is low, so that the laminated films can be peeled from each other in the following processes such as a resist film peeling process or a chemical mechanical polishing (CMP) process. Moreover, a dielectric constant of the CVD film 3 is higher than that of the SOD film 2, thereby increasing a dielectric constant of the entire laminated films.

Therefore, Reference 1 discloses therein laminated films formed of a low dielectric material, wherein insulating film materials are laminated only by a spin coating method to enhance adhesivity between insulating films. Further, Reference 2 discloses therein a method for forming a single polymer dielectric composite layer having a low dielectric property on a base layer and then partially hardening the polymer dielectric composite layer by exposing the polymer dielectric composite layer to electron beams.
[Reference 1] U.S. Pat. No. 6,573,191
[Reference 2] U.S. Pat. No. 6,080,526

However, in the techniques disclosed References 1 and 2, each interlayer insulating film requires a reforming process (curing process) using heat or electron beams. Further, as in Reference 1, when each interlayer insulating film is composed of laminated films, each of the laminated films further requires the curing process using heat or electron beams, thereby deteriorating a throughput. Moreover, since the interlayer insulating films are distributed over multiple layers, a thermal accumulation is getting bigger in an interlayer insulating film positioned at a lower layer and, further, the low dielectric property of the interlayer insulating film considerably deteriorates due to the heat applied in the curing process. Accordingly, a desired low dielectric property cannot be obtained. Besides, an interlayer insulating film formed by the spin coating method has a low mechanical strength.

### SUMMARY OF THE INVENTION

It is, therefore, an object of the present invention to provide a method for reforming laminated films, which is capable of increasing a throughput of a reforming process performed on the laminated films; preventing a deterioration of a low dielectric property; considerably suppressing a delamination by increasing an adhesivity between the laminated films; and improving a mechanical strength of interlayer insulating films, and the laminated films manufactured thereby.

In accordance with an aspect of the invention, there is provided a method for reforming laminated films, which simultaneously reforms a plurality of laminated films by irradiating electron beams on the plurality of laminated films.

In accordance with another aspect of the invention, there is provided a method for reforming laminated films, including the steps of: forming a lower film by coating a first low dielectric material in liquid form on a surface of a substrate; forming an upper film by coating a second low dielectric material in liquid form on the lower film; and irradiating electron beams on the lower and the upper film to thereby simultaneously reform the laminated films.

Further, in the laminated films obtained by employing the method for reforming laminated films, the first and the second low dielectric material preferably have different composition ratios of Si:O:C:H.

Furthermore, in the laminated films, the lower layer made of the first low dielectric material is preferably porous.

Moreover, in the laminated films, the first and the second low dielectric material are preferably methylsilsesquioxane.

In accordance with still another aspect of the invention, there is provided a laminated film manufacturing system including: a mounting table for mounting thereon a substrate on which a plurality of laminated films are formed; and an electron beam unit having a plurality of electron beam tubes for irradiating electron beams on the plurality of laminated films to thereby simultaneously reform the plurality of films.

In accordance with still another aspect of the invention, there is provided a laminated film manufacturing system including: a mounting table for mounting thereon a substrate on which a plurality of laminated films are formed; and an electron beam irradiating means for irradiating electron beams on the plurality of laminated films to thereby simultaneously reform the plurality of films.

Further, in the laminated manufacturing system, the electron beam irradiating means is preferably an electron beam unit having a plurality of electron beam tubes.

### BRIEF DESCRIPTION OF THE DRAWINGS

The above and other objects and features of the present invention will become apparent from the following description of preferred embodiments, given in conjunction with the accompanying drawings, in which:

FIG. 1 shows an electron beam processor used for a laminated film manufacturing method of the present invention;

FIG. 2 illustrates an exemplary arrangement of electron beam tubes of the electron beam processor depicted in FIG. 1;

FIGS. 3A to 3D provide conceptual diagrams describing the laminated film manufacturing process of the present invention;

FIG. 4 presents a graph showing a relationship among a percentage of contraction, a k value and an elastic modulus of a first SOD film;

FIG. 5 represents a cross-sectional view illustrating a wiring structure of a single damascene structure formed in laminated films; and

FIGS. 6A to 6C offer conceptual diagrams illustrating a conventional laminated film manufacturing process.

### DETAILED DESCRIPTION OF THE PREFERRED EMBODIMENT

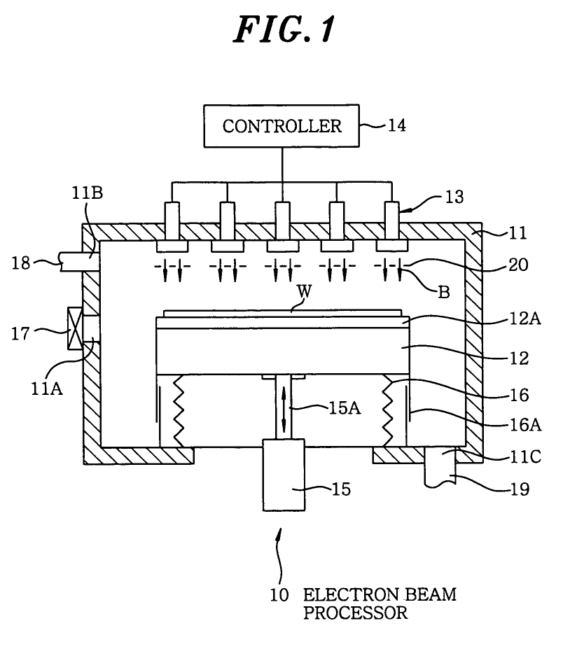

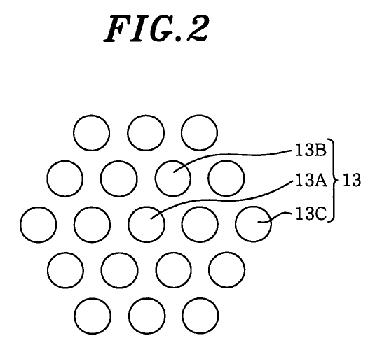

Hereinafter, the present invention will be described based on preferred embodiments illustrated in FIGS. 1 to 5. A laminated film manufacturing method of the present invention employs an electron beam processor shown in FIGS. 1 and 2. By using the electron beam processor, all of laminated films can be simultaneously reformed, thereby considerably increasing a throughput of a reforming process and improving adhesivity between the laminated films. Moreover, the laminated films include a porous lower film for realizing a low dielectric property; and a high density upper film (hard mask) for securing a mechanical strength, wherein the mechanical strength thereof is strengthened by employing an electron beam processing. Hereinafter, the electron beam processor used in this embodiment and the laminated films of this embodiment will be sequentially described.

As illustrated in FIG. 1, an electron beam processor 10 used in this embodiment includes, e.g., a depressurizable processing chamber 11 made of aluminum or the like; a mounting table 12 positioned at a central bottom surface of the processing chamber 11, for mounting thereon an object (wafer) W to be processed; an electron beam unit 13 including a plurality of (e.g., nineteen) electron beam tubes arranged in an approximately concentric circular shape on a top surface of the processing chamber 11 in such a way to face the mounting table 12; and a controller 14 for controlling the mounting table 12, the electron beam unit 13 and the like. The laminated films including two SOD films, the upper and the lower, formed on the wafer W are reformed by irradiating an entire surface of the wafer W mounted on the mounting table 12 with electron beams from the electron beam unit 13 under a control of the controller 14. Hereinafter, the reforming process is referred to as an EB curing process.

An elevating mechanism 15 is connected to a bottom surface of the mounting table 12, and the mounting table 12 moves up and down via a ball screw 15A of the elevating mechanism 15. The bottom surface of the mounting table 12 and that of the processing chamber 11 are connected by an expansible/contractible bellows 16 made of stainless steel and, further, an inner space of the processing chamber 11 is airtightly maintained by the bellows 16. Moreover, a loading/unloading port 11A of the wafer W is formed in a peripheral surface of the processing chamber 11, and a gate valve 17 is attached to the loading/unloading port 11A such that it can be opened and closed. In addition, a gas supply port 11B is formed above the loading/unloading port 11A of the processing chamber 11, and a gas exhaust port 11C is formed at the bottom surface of the processing chamber 11. Furthermore, a gas supply source (not shown) is connected to the gas supply port 11B via a gas supply line 18, and a vacuum exhaust device (not illustrated) is connected to the gas exhaust port 11C via the gas exhaust pipe 19. Besides, a reference numeral 16A in FIG. 1 indicates a bellows cover.

Provided on the top surface of the mounting table 12 is a heater 12A for heating the wafer W to a desired temperature when it is necessary. For example, as illustrated in FIG. 2, the electron beam unit 13 including nineteen electron beam tubes has a first electron beam set containing a single first electron beam tube 13A positioned at a central top surface of the processing chamber 11; a second electron beam set having six second electron beam tubes 13B arranged around the first electron beam set in an approximately concentric circular shape; and a third electron beam set having twelve third electron beam tubes 13C arranged around the second electron beam set in an approximately concentric circular shape, wherein each set is separately controllable. The first, the second and the third electron beam tubes 13A, 13B and 13C have electron beam transmitting windows provided exposedly in the processing chamber 11, respectively. The transmitting windows are sealed by, e.g., transparent quartz glass. Further, grid-shaped detectors 20 are provided under the transmitting windows to opposedly face thereto. The amount of irradiation is detected based on electrons colliding with the detectors 20 and, then, a detection signal is inputted into the controller 14. Based on the detection signal from the detectors 20, the controller 14 controls respective outputs of the first to third electron beam sets having the first to third electron beam tubes 13A to 13C arranged in an approximately concentric circular shape.

Further, the laminated film manufacturing method of the present invention can be characterized with a feature in that the two upper and lower SOD films forming the laminated films can be simultaneously EB-cured by using the electron beam processor 10 of this embodiment. The SOD films forming the laminated films are made of a low dielectric material. The low dielectric material includes a siloxane based (Si—O—Si) material, e.g., Hydrogen-silsesquioxane (HSQ) containing Si, O and H and Methyl-Hydrogen-silsesquioxane (MSQ) containing Si, C, O and H, and an organic material such as polyallylene ether based FLARE commercially available from Honeywell Inc., polyallylene hydrocarbon based SILK commercially available from Dow Chemicals, Parylene, BCB, PTFE, fluorinated polyimide or the like. An MSQ-based organic material includes, e.g., an MSQ-based composite commercially available from JSR Inc.

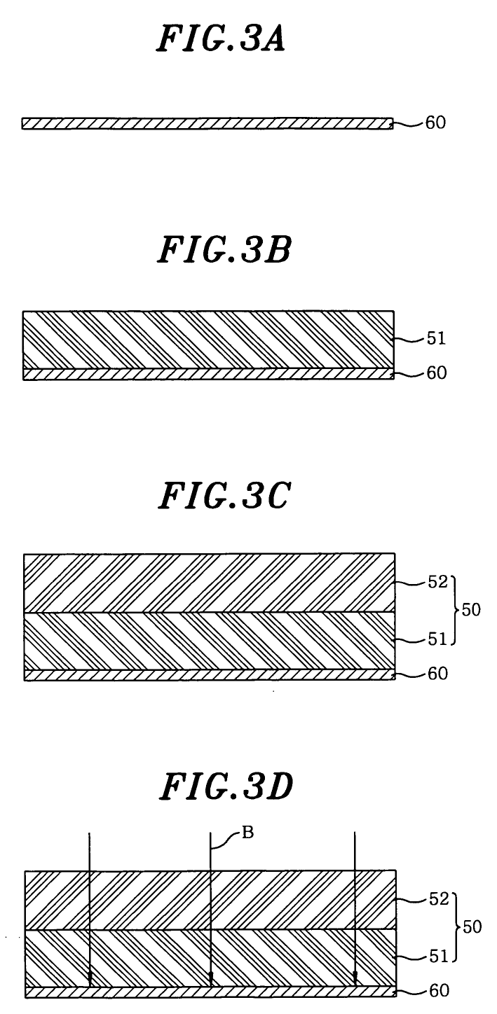

In this embodiment, laminated films 50 are formed by using the MSQ-based composite commercially available from JSR Inc. as a low dielectric material, as depicted in FIGS. 3A to 3D. The laminated films 50 include a first and a second SOD film 51 and 52 formed on a base layer 60 by using a first and a second MSQ-based composite, i.e., a low dielectric material, with a spin coating method. The first MSQ-based composite forming the first SOD film 51 forms a porous insulating film having a low density, thereby realizing a low dielectric property. The second MSQ-based composite forming the second SOD film 52 forms a high density insulating film (hard mask), thereby increasing a mechanical strength in the laminated films 50.

In order to form the laminated films 50, first of all, the first MSQ composite needs to be coated on the base layer 60 (e.g., silicon nitride film) illustrated in FIG. 3A by using a spin coater and, then, a solvent is removed from the first MSQ composite by drying, to thereby form the first SOD film 51 as illustrated in FIG. 3B. Next, the second MSQ composite is coated on the first SOD film 51 by using the spin coater and, then, a solvent is removed from the second MSQ composite. Accordingly, as illustrated in FIG. 3C, the second SOD film 52 is formed while being laminated on the first SOD film 51, thereby obtaining the laminated films 50. Since the first and the second SOD film 51 and 52 are formed of the same kind of MSQ-based composites, they can be easily adhered to each other and have a high adhesivity therebetween. In this embodiment, as shown in FIG. 3D, the EB curing process is carried out by irradiating the laminated films 50 with electron beams.

In other words, as illustrated in FIG. 3D, when electron beams B irradiated to the laminated films 50 transmit through the second and the first SOD film 52 and 51, each of the second and the first MSQ-based composite obtains an activation energy from the electron beams B and then performs a cross-linking reaction. A transmission depth of the electron beams B can be properly controlled by the controller 14. In this case, the first and the second MSQ-based composite are cross-linked in respective films as well as on an interface between the first and the second MSQ-based composite with each other. Thus, it is possible to considerably suppress a delamination between the first and the second SOD film 51 and 52. Further, although the first MSQ-based composite is porous, pores become smaller due to the cross-link reaction caused by the electron beams B and, further, the mechanical strength gets strengthened.

The electron beam processor 10 operates as follows; the wafer W on which the laminated films 50 are formed is transferred to the electron beam processor 10 via an arm of a transfer mechanism (not shown) and, then, the gate valve 17 is opened. Next, the arm of the transfer mechanism transfers the wafer W into the processing chamber 11 through the loading/unloading port 11A and then guides the wafer W on the mounting table 12 prepared in the processing chamber 11. Thereafter, the arm of the transfer mechanism is retreated from the processing chamber 11 and, then, the gate valve 17 is closed, thereby maintaining an inner space of the processing chamber in a sealed state. Meanwhile, the mounting table 12 is raised via the elevating mechanism 15, thereby maintaining a specific distance between the wafer W and the electron beam unit 13.

Next, under the control of the controller 14, air in the processing chamber 11 is exhausted through an exhaust unit and, at the same time, rare gas (e.g., Ar gas) is supplied from a gas supply source into the processing chamber 11, thereby substituting Ar gas for air in the processing chamber 11. Further, the electron beams B are irradiated in the processing chamber 11 while the first to third electron beam tubes 13A to 13C of the electron beam unit 13 are controlled to have a same output. Then, the EB curing process is performed on the laminated films 50 on a surface of the wafer W under the following conditions.

As described in Table 1, two kinds of films for the first SOD film (indicated as “ILD” in Table 1) and one kind of film for the second SOD film (indicated as “HM” in Table 1) were subjected to an EB curing process (indicated as “EB” in Table 1) under the following processing conditions. As shown in Table 1, the first SOD film 51 was formed of porous MSQ-based composites A and B (hereinafter, referred to as “MSQ-A” and “MSQ-B”), whereas the second SOD film 52 was formed of a nonporous MSQ-based composite C (hereinafter, referred to as “MSQ-C”) whose density was higher than that of the first SOD film. Further, in this embodiment, such MSQ films were separately formed and, then, the EB curing process was performed on each of the MSQ films. Thereafter, a refractive index (R.I.), a k value, a pore diameter, a hardness and an elastic modulus of three kinds of MSQ films used as a SOD film were examined. A result thereof is shown in Table 1.

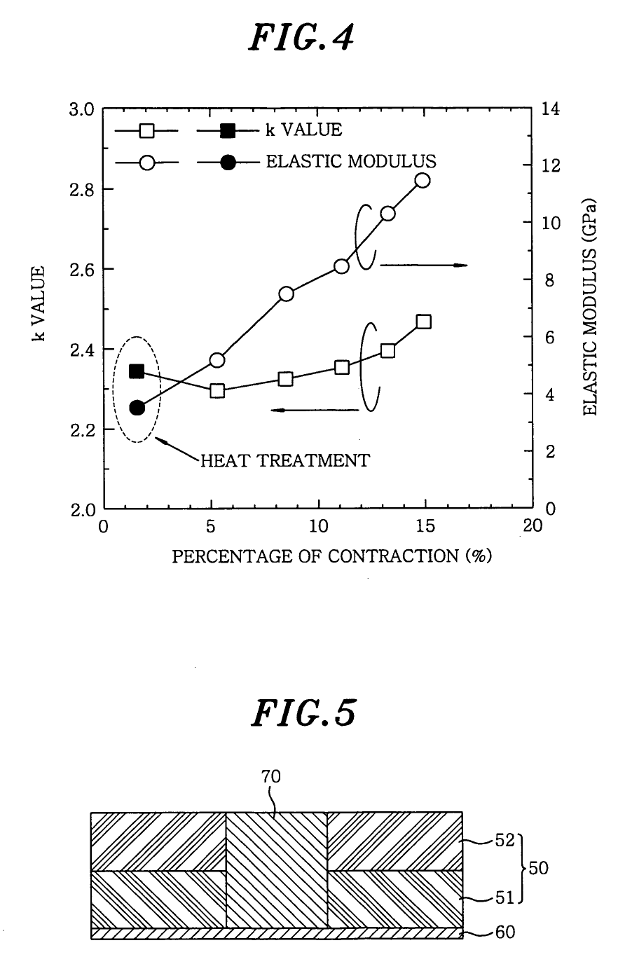

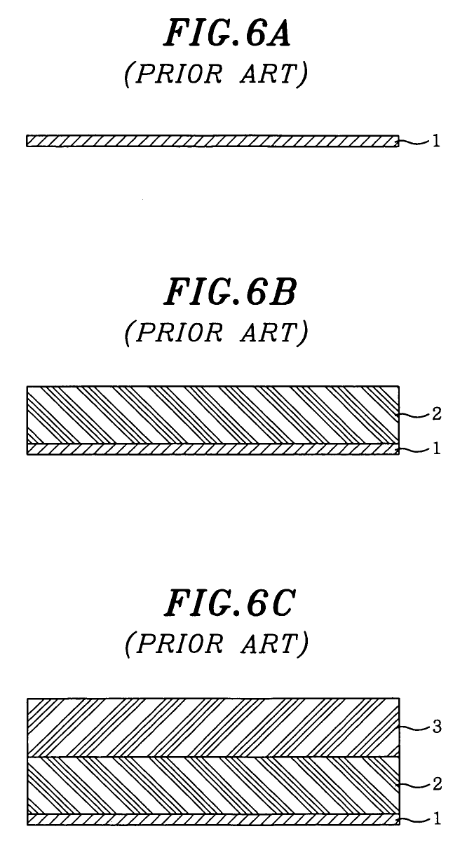

FIG. 4 provides results obtained by performing a heat curing process (indicated by ▪ and ● in FIG. 4) on the MSQ-B film and an EB curing process (indicated by □ and ◯ in FIG. 4) on the heat-cured MSQ-B film. A percentage of contraction, a k value and an elastic modulus of the MSQ-B film are examined, and a relationship therebetween is presented in FIG. 4.

[Processing Conditions]
First SOD film material: MSQ-A and MSQ-B (JSR Inc.)
Second SOD film material: MSQ-C (JSR Inc.)
Average film thickness of first SOD film: 2000 Å
Average film thickness of second SOD film: 1000 Å
Pressure in a processing chamber: 10 Torr
Wafer temperature: 350° C.
Ar gas flow rate: 3 L/min in a standard state (3SLM)
Distance between electron beam tube and wafer: 75 mm
   Electron beam tube
applied voltage: 13 kV
Current in single tube: 250 μA
Wafer diameter: 8 inch

Processing time: 5 min

TABLE 1

| | |
|---|---|
| ILD | HM |

| | | | |
|---|---|---|---|
| Low dielectric material | MSQ-A | MSQ-B | MSQ-C |
| Curing process | EB | EB | EB |
| R.I. | 1.27 | 1.3 | 1.39 |
| K value | 2.26 | 2.36 | 2.88 |
| Pore diameter (mm) | 1.7 | 1.2 | — |
| Hardness (Gpa) | 1.0 | 1.3 | 2.0 |
| Elastic modulus (Gpa) | 7.0 | 8.5 | 15 |

From the results shown in Table 1, both films (hereinafter referred to as “MSQ-A film” and “MSQ-B film”) made of MSQ-A and MSQ-B, i.e., porous MSQ-based composites, capable of realizing a low dielectric property, are found to have an R.I., a k value, a hardness and an elastic modulus that are suitable for a first SOD film. In other words, the first SOD film preferably has an R.I. value greater than or equal to 1.25, a k value smaller than or equal to 2.4, a hardness greater than or equal to 0.8 GPa and an elastic modulus greater than or equal to 5 GPa. As can be clearly seen from the results shown in Table 1, the MSQ-A film and the MSQ-B film have properties suitable for the first SOD film. Specifically, the MSQ-A film of a large pore diameter has a small k value suitable for the first SOD film requiring the low electric property, but it has a slightly low mechanical strength as can be known from the R.I., the hardness and the elastic modulus i.e., indexes related to a mechanical strength. On the other hand, although the MSQ-B film that has a small pore diameter has a k value slightly greater than that of the MSQ-A film, the R.I., the hardness and the elastic modulus thereof are also slightly greater than those of the MSQ-A film. Accordingly, in comparison with the MSQ-A film, the MSQ-B film is more suitable for the first SOD film requiring the mechanical strength. That is, the k value and the mechanical strength of the porous MSQ film are reciprocal to each other. Therefore, depending on the k value and the mechanical strength required for laminated films, it is preferable to use as the first SOD film the MSQ film having proper k value and mechanical strength.

Further, it is known from the results shown in Table 1 that a film (hereinafter, referred to as “MSQ-C film”) made of MSQ-C, i.e., a nonporous MSQ-based composite, has the R.I., the hardness and the elastic modulus that are considerably greater than those of the MSQ-A film and the MSQ-B film; and the k value of 2.88. As the second SOD film, it is preferable to employ the nonporous MSQ film having a high density and an enhanced mechanical strength. Moreover, in order to prevent a deterioration of the low dielectric property of the laminated films, the k value of the second SOD film needs to be small. In order to satisfy such conditions required in the second SOD film, it is preferable that the second SOD film has the k value smaller than or equal to 2.9, the R.I. value greater than or equal to 1.35, the hardness greater than or equal to 1.5 GPa and the elastic modulus greater than or equal to 10 GPa. As can be clearly seen from the result shown in Table 1, the MSQ-C film has the aforementioned properties suitable for the second SOD film.

Besides, from the results illustrated in FIG. 4, it can be found that when the EB curing process is performed until a percentage of contraction of the MSQ-B film reaches 10% or less, the k value increases only a few percentages, whereas the mechanical strength is almost doubled. Further, it also can be found that when the percentage of contraction of the MSQ-B film exceeds 10% due to an excessive EB curing process, the mechanical strength increases, but k value also increases accordingly. Such results show that the excessive EB curing process increases not only the mechanical strength but also the k value. Therefore, when the EB curing process is performed on the laminated films, the EB curing process is preferably performed only once so that the lower film can be prevented from being excessively EB-cured due to the EB curing process performed on each film.

The EB curing process is performed once on the laminated films including the first and the second SOD film respectively made of the MSQ-B and the MSQ-C. Next, a section of the laminated films was photographed by a scanning electron microscope (SEM) and, then, an SEM image was observed. From the result of the observation, a penetration of the MSQ-C into a pore of the porous MSQ-B or a mixture of materials in a boundary between the MSQ-B film and the MSQ-C film was not observed. When the MSQ-A was used as the first SOD film, the same result was obtained. Further, when a single damascene structure of a Cu wiring 70 illustrated in FIG. 5 is formed in the laminated films 50 and, then, the Cu wiring 70 is polished by a CMP process, a delamination between the first and the second SOD film 51 and 52 is not observed. Furthermore, in an MISCAP structure of the laminated films including MSQ-B and MSQ-C, the k value is 2.6, and the low dielectric property is found not to be deteriorated in spite of laminated films.

As described above, in accordance with this embodiment, the electron beams B are irradiated to the first and the second SOD film 51 and 52 of the laminated films 50, thereby reforming the first and the second SOD film 51 and 52 simultaneously. Therefore, a throughput of the reforming process can be considerably increased. Besides, since the heat treatment is not carried out, it is possible to suppress or prevent the dielectric constant of the first and the second SOD film 51 and 52, especially, the first SOD film 51, from being increased due to a thermal accumulation. Accordingly, if the films are more laminated, the more effective and desired low dielectric constant can be obtained.

Moreover, in accordance with this embodiment, the adhesivity between the first and the second SOD film 51 and 52 of the laminated films 50 can be increased and, at the same time, the mechanical strength can be increased. As a result, it is possible to prevent the delamination in the following processes such as a resist film peeling process or a CMP process.

Although the interlayer insulating film is described as an example in the aforementioned embodiment, the present invention can be applied to laminated films serving as a coating film. For example, a spin-on-glass (SOG) film, a resist film or a reflective film can be formed as the laminated films. In addition to the coating film, the present invention can be applied to a CVD film, a sputter film, a plated film or the like as long as the films can be subjected to a film reforming process, e.g., a hardening, a transformation or the like, using an electron beam irradiation.

Although the above embodiment has described the two-layer film as a multilayer film, the present invention can be applied to a three- or more-layer film. For example, it is possible to perform simultaneously the EB curing process after porous-MSQ, organic low k (SiLK) and MSQ (nonporous) films are sequentially spin-coated on a base layer.

Moreover, although a plurality of electron beam tubes are arranged in an approximately concentric circular shape in this embodiment, they can be arranged in another shape enabling electron beams to be uniformly irradiated on an object to be processed.

In a laminated film manufacturing system, a single processor may be arranged to have therein a film forming processor (a spin coater) and an electron beam processor as processing units and, further, a wafer can be made to be transferred between processing units by a wafer transfer mechanism.

While the invention has been shown and described with respect to the preferred embodiments, it will be understood by those skilled in the art that various changes and modification may be made without departing from the spirit and scope of the invention as defined in the following claims.

1. A method for reforming laminated films, which simultaneously reforms a plurality of laminated films by irradiating electron beams on the plurality of laminated films.

2. A method for reforming laminated films, comprising the steps of:
forming a lower film by coating a first low dielectric material in liquid form on a surface of a substrate;
forming an upper film by coating a second low dielectric material in liquid form on the lower film; and
irradiating electron beams on the lower and the upper film to thereby simultaneously reform the films.

3. Laminated films formed by using the method of claim 2, wherein the first and the second low dielectric material have different composition ratios of Si:O:C:H.

4. The laminated films of claim 3, wherein the lower layer made of the first low dielectric material is porous.

5. The laminated films of claim 3, wherein the first and the second low dielectric material are methylsilsesquioxane.

6. A laminated film manufacturing system comprising:
a mounting table for mounting thereon a substrate on which a plurality of laminated films are formed; and
an electron beam unit including a plurality of electron beam tubes for irradiating electron beams on the plurality of laminated films to thereby simultaneously reform the plurality of films.

7. A laminated film manufacturing system comprising:
a mounting table for mounting thereon a substrate on which a plurality of laminated films are formed; and
an electron beam irradiating means for irradiating electron beams on the plurality of laminated films to thereby simultaneously reform the plurality of films.

8. The laminated film manufacturing system of claim 7, wherein the electron beam irradiating means is an electron beam unit including a plurality of electron beam tubes.
